(19) United States
(12) Patent Application Publication
(10) Pub. No.: US 2015/0293567 A1
(43) Pub. Date: Oct. 15, 2015

(54) SECONDARY COOLING SYSTEM FOR LAPTOP COMPUTER

(71) Applicants: Ray Broadwell, Grand Forks, ND (US); Linda Broadwell, Grand Forks, ND (US)

(72) Inventors: Ray Broadwell, Grand Forks, ND (US); Linda Broadwell, Grand Forks, ND (US)

(21) Appl. No.: 14/557,356

(22) Filed: Dec. 1, 2014

Related U.S. Application Data
(63) Continuation of application No. 14/248,497, filed on Apr. 9, 2014, now abandoned.

(51) Int. Cl. G06F 1/20; H05K 7/20

(52) U.S. Cl. CPC G06F 1/203; H05K 7/20136

(57) ABSTRACT

A cooling system for a laptop computer comprising a cooling fan installed in a battery compartment of the laptop computer, where a battery is removed from the battery compartment, where the cooling fan includes an internal fan to blow cool air into a RAM compartment without a cover; and a plurality of lifts attached to a bottom surface of a base of the laptop computer, where the plurality of lifts raise the base above an underlying surface. With the cooling fan and lifts more cool air is able to blow over the internal components of the laptop.

### CROSS REFERENCE TO OTHER APPLICATIONS

This application is a continuation to U.S. patent application Ser. No. 14/248,497 filed on Apr. 9, 2014.

### BACKGROUND OF THE INVENTION

1. Field of the Invention

The present invention relates to a cooling system installed into a laptop to further cool the internal components of the laptop and to help prevent them from overheating.

2. Description of Related Art

Most households have at least one computing device, either a desktop or laptop, for the individual or family to use. Desktops are typically larger and more powerful than the smaller, more portable laptops, so they are preferred to operate more complex processing systems and games. On the other hand, laptops are convenient because internet availability is so easily accessible, thus many people carry their laptops with them at all times in order to access the plethora of wireless networks. The laptops are allow the user to do homework, conduct business dealings, watch movies, listen to music and surf the web all while away from home.

Because of their small size, laptop computers do not have large cooling systems like their larger predecessors. This may limit the amount of time spent or eliminate all together running more complex operating systems, because the internal hardware heats and overheats during extended use. Overheating may cause the internal processors to be ruined from the heat exposure. Many times when the user feels their laptop start to heat up, they must stop running the program they're using otherwise risk permanent damage.

Therefore it would be beneficial in the art to provide a cooling means that supports the existing system within the laptop to allow a user to use their laptop for a longer period of time. It would also be desirable in the art to provide a cooling means that is easily adaptable to already existing laptops.

### SUMMARY OF THE INVENTION

In view of the foregoing disadvantages inherent in the prior art, the general purpose of the present invention is to provide a cooling system for a laptop computer, configured to include all of the advantages of the prior art, and to overcome the drawbacks inherent therein.

Accordingly, an object of the present invention is to provide a cooling system for a laptop where the system includes a cooling fan to blow cool air onto the internal components of the laptop.

Another object of the present invention is to provide a cooling system with a set of lifts to raise the base of the laptop thereby allowing additional air to pass beneath the laptop during use.

To achieve the above objects, in an aspect of the present invention, a cooling system for a laptop computer is described comprising a cooling fan installed in a battery compartment without a battery, where the cooling fan includes an internal fan to blow cool air into a RAM compartment without a cover; and a plurality of lifts attached to a bottom surface of a base of the laptop computer, where the plurality of lifts raise the base above an underlying surface. With the cooling fan and lifts more cool air is able to blow over the internal components of the laptop.

These together with other aspects of the present invention, along with the various features of novelty that characterize the present invention, are pointed out with particularity in the claims annexed hereto and form a part of this present invention. For a better understanding of the present invention, its operating advantages, and the specific objects attained by its uses, reference should be made to the accompanying drawings and descriptive matter in which there are illustrated exemplary embodiments of the present invention.

### BRIEF DESCRIPTION OF THE DRAWINGS

The advantages and features of the present invention will become better understood with reference to the following detailed description and claims taken in conjunction with the accompanying drawings, wherein like elements are identified with like symbols, and in which:

FIG. 1 depicts a bottom view of a laptop with a secondary cooling system in accordance with an exemplary embodiment of the present invention; and

FIG. 2 depicts a side view of a laptop with a secondary cooling system in accordance with an exemplary embodiment of the present invention.

Like reference numerals refer to like parts throughout the description of several views of the drawings.

### DETAILED DESCRIPTION OF THE DRAWINGS

The present invention relates to a cooling fan installed in a laptop to further cool the internal components of the laptop and to help prevent them from overheating. The present invention provides a secondary cooling system as an additional cooling means to the conventional cooling systems already found in a laptop. The secondary cooling system is easily installed by replacing the battery within the laptop with a cooling fan. The fan couples with the internal power system of the computer to keep the fan operating while the laptop is plugged into an outlet. During use, the cover of the RAM is removed to expose the internal components of the laptop. As such, the fan blows cool air onto the delicate internal components within the laptop to maintain optimal operating temperatures.

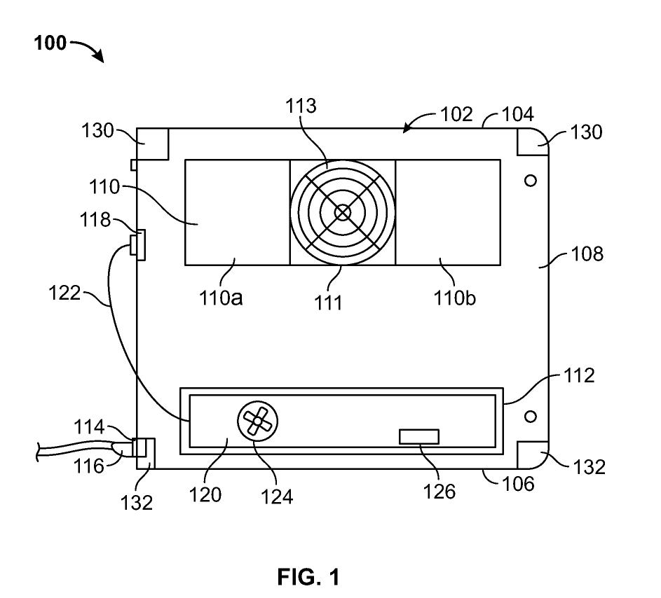

Turning now descriptively to the drawings, referring to FIG. 1, a laptop with a secondary cooling system 100 is shown in accordance with an exemplary embodiment of the present invention. The secondary cooling system 100 is positioned within the base 102 of the laptop. The base 102 includes a front end 104, a back end 106 and a bottom surface 108. As illustrated on the bottom surface 108, the base 102 includes at least one hard drive compartment 110, a RAM compartment 111, and a battery compartment 112. As illustrated, the laptop includes a first covered hard drive compartment 110a and a second covered hard drive compartment 110b.

During use, the cover for the RAM compartment 111 is removed and replaced with a grate 113. The grate 113 may be metal or plastic, and it allows cool air to pass through the RAM compartment 111. Additionally the cover and battery from the battery compartment 112 are removed. Since the battery is removed, a power cord 116 plugged into a power port 114 must be attached to allow the laptop to withdraw power from an electrical outlet.

Within the battery compartment 112 a cooling fan 120 is installed. The cooling fan 120 couples with the internal power system of the laptop to operate an internal fan 124. The internal fan 124 rotates fast enough to generate a small breeze which is then blown over the opened RAM compartment 111 to cool the hard drive. The grate 113 enables air to pass through the laptop computer from the battery compartment 112 and out the RAM compartment 111. The cooling fan 120 may encompass the entire battery compartment 112 to ensure a snug and secure fit. An on/off button 126 may be attached to the cooling fan 120 to activate the fan 124. Since the cooling fan 120 is powered by the internal power system of the laptop, it cannot be activated with the on/off button 126 until the laptop computer is plugged into the electrical outlet. The cooling fan 120 may be a five volt electric computer fan which includes a USB cord 122 that plugs into a USB port 118 within the base 102.

On the base 102 a set of lifts 130, 132 are attached. Preferably the lifts 130, 132 are positioned at the corners of the base 102, wherein a first pair of lifts 130 is attached at the front end 104 and a second pair of lifts 132 is attached at the back end 106. The lifts 130, 132 raise the base 102 from the underlying surface to enable additional external air to pass beneath the base 102 when in use; thereby providing more air for the cooling fan 120 to circulate.

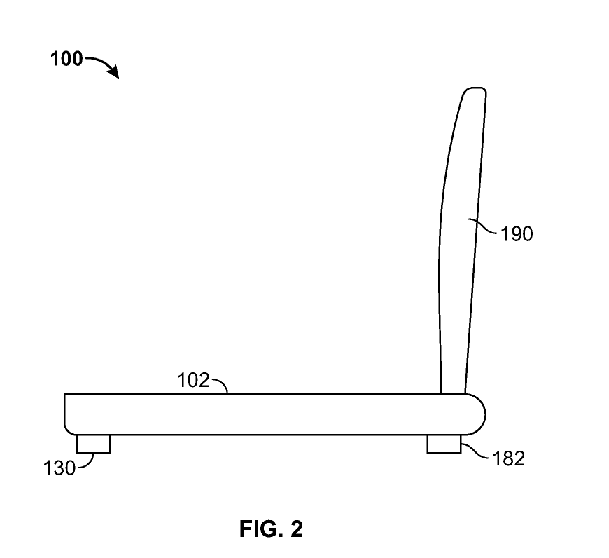

Referring now to FIG. 2, a side view of the laptop is shown with the secondary cooling system 100. The first pair of lifts 130 may raise the front end 104 approximately 0.5 inches. The second pair of lifts 132 may raise the back end 106 approximates 0.75 inches. With the second pair of lifts 132 taller than the first pair of lifts 130 the base 102 rests at an angle to provide more air to the cooling fan 120. Also, the angled base 102 lifts the cover 140 and gives the user a more ergonomic keyboard to reduce hand strain and fatigue while typing. The secondary cooling system 100 is easily installed into an already existing computer to allow the laptop to perform at the ideal temperature, thereby helping to prevent overheating after extended use.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The exemplary embodiment was chosen and described in order to best explain the principles of the invention and its practical application, to thereby enable others skilled in the art to best utilize the invention and various embodiments with various modifications as are suited to the particular use contemplated.

What is claimed is:

1. A cooling system for a laptop computer comprising:
a. a cooling fan installed in a battery compartment of the laptop computer, where a battery is removed from the battery compartment, and where the cooling fan includes an internal fan to blow cool air into a RAM compartment without a cover; and
b. a plurality of lifts attached to a bottom surface of a base of the laptop computer, where the plurality of lifts raise the base above an underlying surface.

2. The cooling system for a laptop computer according to claim 1, where the cooling fan includes a USB cord to plug into a USB port within the base.

3. The cooling system for a laptop computer according to claim 1, where the cooling fan includes an on/off button to activate the internal fan.

4. The cooling system for a laptop computer according to claim 1, where the plurality of lifts include a first pair of lifts and a second pair of lifts, where the first pair of lifts is positioned at a front end of the base and where the second pair of lifts is position at a back end of the base.

5. The cooling system for a laptop computer according to claim 4, where the first pair of lifts are 0.5 inches tall and the second pair of lifts are 0.75 inches, where the base rests at an angle to enable air to pass beneath the base.

6. The cooling system for a laptop computer according to claim 1, where the RAM compartment includes a grate, where the grate enables cool air from the cooling fan to pass through the RAM compartment.

7. A method of use for a cooling system for a laptop computer comprising the steps of:
a. removing a cover from a RAM compartment within a base of the laptop computer;
b. removing a cover and a battery from a battery compartment within the base;
c. installing a cooling fan within the battery compartment;
d. plugging a USB cord from the cooling fan into a USB port within the base;
e. positioning the base on a plurality of lifts to raise the base above an underlying surface;
f. powering on the laptop computer; and
g. cooling the laptop computer with the cooling fan blowing air from the battery compartment through the RAM compartment.

8. The method of use for a cooling system for a laptop computer according to claim 7 further comprising the step of activating an internal fan within the cooling fan with an on/off button.
